(19) United States
(12) Patent Application Publication
(10) Pub. No.: US 2003/0007500 A1
(43) Pub. Date: Jan. 9, 2003

(54) Fault-tolerant system for routing between autonomous systems

(75) Inventors: Jean-Pierre Rombeaut, Maubeuge (FR); Bruno Mongazon-Cazavet, Michel-Sur-Orge (FR)

Correspondence Address: SUGHRUE MION, PLLC, Suite 800, 2100 Pennsylvania Avenue, N.W., Washington, DC, 20037-3213, US

(73) Assignee: ALCATEL

(21) Appl. No.: 10/189,490

(22) Filed: Jul. 8, 2002

(30) Foreign Application Priority Data
Jul. 9, 2001 (FR) 01 09 086

(51) Int. Cl. H04J 3/17; G01R 31/08; H04L 12/28

(52) U.S. Cl. 370/433; 370/244; 370/400

(57) ABSTRACT

A system for routing between autonomous systems connected to peer routers, the system comprising, for each peer router, two routing modules enabling routing to be performed between autonomous systems, only one of the modules being in an active state at any given instant, the others being in a standby state, and means enabling one of said other routing modules to switch from a standby state to an active state in the event of the routing module that is in the active state stopping.

The present invention relates to ensuring continuity of service in a routing system within an Internet type network. More precisely, the invention relates to routing between autonomous systems in accordance with the Border Gateway Protocol (BGP) as defined in Request for Comments (RFC) 1771 of the Internet Engineering Task Force (IETF). It also applies to earlier versions of said protocol such as the Exterior Gateway Protocol (EGP) defined by IETF RFC 904.

### BACKGROUND OF THE INVENTION

As shown in FIG. 1, such a network is made up of autonomous systems (AS₁, AS₂, AS₃). Each autonomous system possesses a coherent and unique routing plan relative to the other routing systems.

Two sorts of routing protocol can be distinguished:

protocols for routing within an autonomous system which seek to establish said routing plans within an autonomous system. One example of such a protocol is the Open Shortest Path First (OSPF) routing protocol a defined in IETF RFC 2328; and

protocols for routing between autonomous systems which seek to exchange said routing plans so as to enable routing between autonomous systems.

In FIG. 1, continuous lines between routers represent communications using the OSPF protocol.

Protocols for routing between autonomous systems, such as BGP, are typically implemented by border routers BR₁, BR₂, BR₃. These border routers can communicate with one another and therefore interchange routing information. They thus form a sub-network. For communication between border routers of different autonomous systems, the behavior of the BGP protocol is known as Exterior Border Gateway Protocol (EBGP) and is represented in FIG. 1 by dashed lines.

This sub-network may also include routers for use within an autonomous system and enabling the Interior Gateway Protocol (IGBP) to be implemented which is how the BGP protocol behaves for routers within autonomous systems. Communications using this protocol are represented by dotted lines in FIG. 1.

Typically, with BGP type protocols (i.e. including IBGP, EBGP, . . . ), the routing information that is exchanged comprises routes.

Each other router (and in particular each border router) with which a border router communicates is referred to below as a peer router or more simply as a peer.

This therefore implies that border routers are crucial elements of the network. If, following a failure for example, they can no longer perform their routing service, the operation of the network is compromised, or in any event requires reorganization which can be penalizing.

### OBJECTS AND SUMMARY OF THE INVENTION

Thus, it is important to ensure continuity of the routing service, in particular of the service provided by border routers.

To do this, the invention provides a system for routing between autonomous systems connected to peer routers. For each peer router, the system comprises:

two routing modules enabling routing to be performed between autonomous systems, only one of the modules being in an active state at any given instant, the others being in a standby state; and

means enabling one of said other routing modules to switch from a standby state to an active state in the event of the routing module that is in the active state stopping.

In an implementation of the invention, said routing modules comply with a BGP type protocol.

In an implementation of the invention, each routing module has:

means operative in the active state to store information relating to its state and to the associated peer router; and

means for recovering said information when said routing module changes over into the active state.

Thus, by means of this redundancy mechanism and by storing information possessed by the active routing modules and those on standby, the routing service can be constantly in operation. In the event of a failure, the sub-network will continue to operate normally, without the failure having any repercussion on its behavior.

### BRIEF DESCRIPTION OF THE DRAWINGS

The invention and its advantages appear more clearly in the following description of an implementation of the invention given with reference to the accompanying figures.

FIG. 1, described above, shows the architecture which is typical of an Internet type network.

FIG. 2 shows a state machine corresponding to the BGP protocol.

### MORE DETAILED DESCRIPTION

Conventionally, the system for routing between autonomous systems of the invention is implemented within an Internet router. Still more precisely, it can be implemented within a border router.

Nevertheless, the system for routing between autonomous systems can also be implemented within a router for routing within an autonomous system or even within equipment other than a router. In other words, it also applies to the IBGP and EBGP protocols.

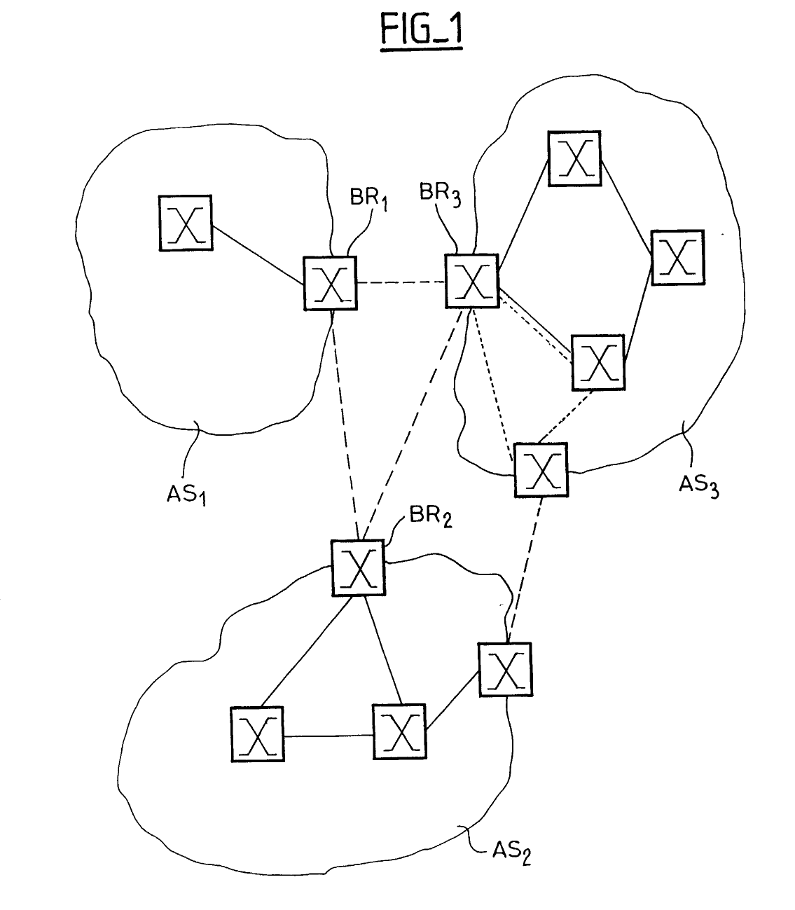

The BGP protocol can be represented by a finite state machine. Such a finite state machine can be defined for each peer to which the system for routing between autonomous systems is connected. Thus, in FIG. 1, the border router BR₁ has two sets of routing modules for each peer BR₂ and BR₃, each of said routing modules implementing a BGP finite state machine.

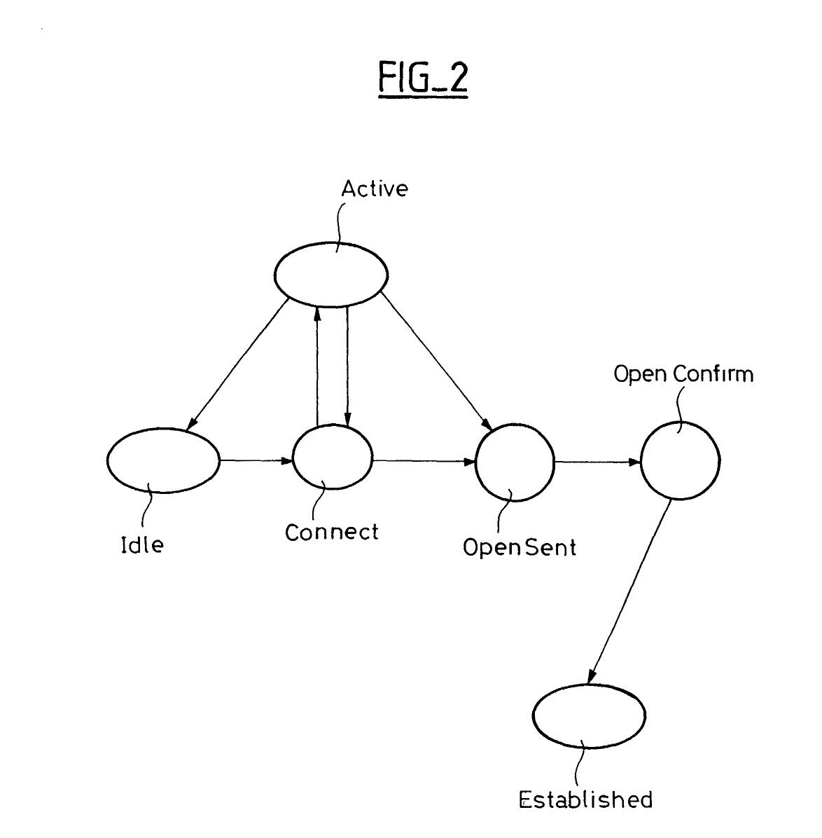

FIG. 2 shows such a finite state machine.

The first state is the “idle” state. This is the initial state from which the finite state machine starts. In this state, the routing system possesses only basic information about the peer.

In an implementation of the invention, this basic information is stored so as to be capable of being taken into account in the event of a switchover to a routing module on standby.

The basic information can comprise the following:

the Internet protocol (IP) address of the peer;

its identifier; and

the state of the state machine (more precisely of the state machine associated therewith).

On receiving a “Start” event, the finite state machine switches to a “Connect” state. A connection at transport protocol level is then initiated with the peer router.

In an implementation of the invention, this transport protocol is a fault-tolerant Transport Control Protocol (TCP). Numerous fault-tolerant TCPs exist. Mention can be made of the protocol described in the article “Wrapping server-side TCP to mask connection failures” by Lorenzo Alvisi, Thomas C. Bressoud, A. El-Khashab, K. Marzullo, and D. Zagorodnov, Technical Report, Department of Computer Sciences, The University of Texas, Austin, July 2000.

Mention can also be made of the HydraNet-FT protocol as described in particular in the article “Hydranet-FT: network support for dependable services” by G. Shenoy, S. Satapati, and Riccardo Bettati, published in the “Proceedings of the 20th International Conference on Distributed Computing Systems”, May 2000.

In the event of a failure, the finite state machine switches to the “Active” state which consists in waiting for a TCP connection from the peer. After a certain length of time has elapsed, and if no TCP connection attempt has succeeded, the finite state machine switches back to the “Connect” state so as to reinitiate an attempt at TCP connection.

Once TCP connection has finally been established, the routing module transmits a “Open” message and the finite state machine switches to the “OpenSent” state.

In this state, the routing module waits to receive a “Open” message from the peer. On receiving such a message, the finite state machine switches to the “OpenConfirm” state.

In this state, the finite state machine waits to receive a “KeepAlive” message. These “KeepAlive” messages are regularly exchanged by modules for routing within autonomous systems in order to inform one another that they are still in operation.

On receiving a “KeepAlive” message, the connection is considered as being established and the finite state machine switches to the “Established” state.

In this state, the finite state machine receives “KeepAlive” messages and “Update” messages. These “Update” messages contain routing information, i.e. new routes, or route cancellations.

According to the invention, on each change of state, the new state is stored so that the standby routing module can start directly from that state.

Thus, there is no need to go back through the succession of states as described above, and changeover from one routing module to another is transparent for the peer.

In an implementation of the invention, in addition to the basic information which is stored when the finite state machine is in the “Idle” state, the routing information received from the peer router is also stored (regardless of whether this information concerns new routes or route cancellations).

This storing can be achieved by means of a memory that is shared between the active routing module and the standby routing module(s).

Other implementations are naturally possible and within the competence of the person skilled in the art. In particular, the routing modules can communicate via an inter-process communication means. By way of example, such inter-process communication means can be a software bus such as the CORBA software bus complying with the Object Management Group (OMG) specifications. The storage step can then be preceded by a step of sending information to the standby routing module(s) with it being their responsibility to store said information in such a manner as to enable them to recover it in the event of a change of state.

When the routing module in the active state stops (whether because of a program stop or because of a failure), one of the standby routing modules becomes active. It can then take account of the information stored by the previously active routing module.

Firstly, the state of the finite state machine associated with the newly active routing module can be forced to take up the stored state (i.e. the state of the previously active routing module prior to stopping).

Secondly, the newly active routing module can take account of information about the peer router (as mentioned above, its IP address, etc.), together with the routing information received therefrom.

1/ A system for routing between autonomous systems connected to peer routers, the system comprising, for each peer router, two routing modules enabling routing to be performed between autonomous systems, only one of the modules being in an active state at any given instant, the others being in a standby state, and means enabling one of said other routing modules to switch from a standby state to an active state in the event of the routing module that is in the active state stopping.

2/ A routing system according to claim 1, in which said routing modules comply with a BGP type protocol.

3/ A routing system according to claim 1, in which each of said routing modules has means operative in the active state to store information relating to its state and to the associated peer router, and means for recovering said information when said routing module changes over into the active state.

4/ A routing system according to the preceding claim, in which said routing information comprises the state of the finite state machine associated with said routing module, the routing module changing over to the active state being forced into said state.

5/ A routing system according to the preceding claim, in which said information further comprises information about the associated peer router and the routing information received from said associated peer router.

6/ A router including a routing system according to claim 1.
